(19) United States
(12) Patent Application Publication
(10) Pub. No.: US 2017/0040971 A1
(43) Pub. Date: Feb. 9, 2017

(54) CRYSTAL OSCILLATORS AND METHODS FOR FABRICATING THE SAME

(71) Applicant: EMPIRE TECHNOLOGY DEVELOPMENT LLC, Wilmington, DE (US)

(72) Inventor: Naoya Ichimura, Osaka (JP)

(73) Assignee: EMPIRE TECHNOLOGY DEVELOPMENT LLC, Wilmington, DE (US)

(21) Appl. No.: 15/115,622

(22) PCT Filed: Jan. 30, 2014
(86) PCT No.: PCT/US14/13877

§ 371 Date: Jul. 29, 2016

(51) Int. Cl. H03H 9/19; G01N 29/46; G01N 29/036; G01N 29/02; H03H 9/125; G01N 29/24

(52) U.S. Cl. CPC H03H 9/19; H03H 9/125; G01N 29/2443; G01N 29/036; G01N 29/022; G01N 29/46; G01N 2291/02408; G01N 2291/0426

(57) ABSTRACT

Crystal oscillators and methods for fabricating the crystal oscillators are disclosed. Also disclosed are sensors comprising the crystal oscillators, and methods for detecting an analyte using the sensors. In some embodiments, a crystal oscillator can include a convex crystal resonator having a first surface and a second surface, wherein the first surface comprises at least one convex-shaped portion and the second surface is substantially planar; at least one pair of first electrodes disposed on the first surface; and at least one second electrode disposed on the second surface.

### BACKGROUND

Unless otherwise indicated herein, the materials described in this section are not prior art to the claims in this application and are not admitted to be prior art by inclusion in this section.

Crystal oscillators can be installed in portable electronic equipment, such as portable computers, mobile phones, smart phones, and so on, as small surface-mounted electronic components that supply a reference source of frequency or time. They can be wired in such a way so as to suspend a crystal substrate over a ceramic substrate, and can be supplied for consumer use in a form whereby the entire oscillator can be concealed by a cover.

However, in conventional surface-mounted crystal oscillators, a miniaturized crystal element is electrically connected by an electrically conductive adhesive so that it can be suspended in air whilst ensuring that the lead-out terminal extending from the crystal holding terminal to the electrode does not short. This, in addition to the structure whereby the entire oscillator is covered by a metal component, makes it difficult to reduce the rate of defects, to increase productivity, and to improve quality.

In addition, conventional surface-mounted crystal oscillators are generally formed by holding, at its edges, a small crystal element of the crystal oscillator with a size of approximately 5 mm×5 mm and suspending it in air in a metal case. Because the crystal element is small, the resonant driving energy is small, and can be difficult to produce resonance because the oscillation energy is distributed throughout the entire crystal plate. Accordingly, resonant oscillations are difficult to produce depending on the conditions of the wiring used to suspend the oscillator in the air. Also, it is necessary to electrically wire the surface and the reverse side of the crystal element individually because electrodes must be deployed on both sides of the crystal element. This produces structural complexity, making miniaturization difficult, and manufacturing costs are increased due to this structural complexity.

Conventional surface-mounted crystal oscillators also require a structure whereby the entire crystal element is suspended in air in order to convert the physical oscillation of the entire crystal element into an electrical oscillation. For this purpose, electrodes arranged on both sides of the crystal element and extending to the edges of the element, where electrical wiring connections are made with the oscillation circuit on the substrate. Since there are electrodes on both sides of the crystal surface, it is necessary for the surface-mounted element to have the electrodes wiring on only one side of the crystal element and to suspend the entire crystal element in air within the metal case in order to make the electrodes on the crystal element oppose the circuit electrodes of the substrate oscillation circuit, which makes the element structurally complex.

Crystal oscillators are being investigated for application to odor or gas sensors. Among sensors corresponding to the five human senses (sight, hearing, touch, taste, and smell), sensors associated with sight, hearing, and touch, which utilize physical stimuli, have been developed and are being put to practical use. In contrast, the development and application of sensors associated with taste or smell, which can detect chemical substances, is generally under development. In addition, there is a large demand for small sensors such as those that can be installed in mobile devices, and so on.

Innovations allowing miniaturization of crystal oscillators in the form of electronic components are necessary for their application to mobile devices. When using a conventional surface-mounted crystal oscillator, the structure is such that just the edge of the crystal oscillator is wired in the metal case so as to suspend it in air within the casing. This makes it difficult to reduce the size of the component for installation in mobile applications since some three-dimensional space is necessary. In addition, for an odor sensor, in order to obtain characteristics that respond to various odor components, it is necessary to package multiple surface-mounted crystal oscillators, corresponding in number to the variety of odors to be sensed, inside a metal case. This makes it difficult to realize mobile applications where size and thickness are restricted. Therefore, there is a need for developing compact crystal oscillators that are small and thin.

### SUMMARY

Crystal oscillators and methods for fabricating the crystal oscillators are disclosed. Also disclosed are sensors including the crystal oscillator, and methods for detecting an analyte using the sensors.

In some embodiments, the crystal oscillator can include: a convex crystal resonator having a first surface and a second surface, wherein the first surface comprises at least one convex-shaped portion and the second surface is substantially planar; at least one pair of first electrodes disposed on the first surface; and at least one second electrode disposed on the second surface.

In some embodiments, the method for fabricating a crystal oscillator can include: providing a crystal substrate; forming at least one convex portion in the crystal substrate; forming at least one pair of first electrodes on a first surface of the at least one convex portion of the crystal substrate; and forming at least one second electrode on a second surface of the at least one convex portion of the crystal substrate.

In some embodiments, the sensor can include: a crystal oscillator, comprising a convex crystal resonator having a first surface and a second surface, wherein the first surface comprises at least one convex-shaped portion and the second surface is substantially planar; at least one pair of first electrodes disposed on the first surface; and at least one second electrode disposed on the second surface; and a material disposed on the second electrode, wherein the material is sensitive to an analyte.

Some embodiments provide a method for detecting an analyte, where the method can include: providing a sample suspected of containing an analyte; contacting a sensor with the sample, wherein the sensor comprises a crystal oscillator, comprising a convex crystal resonator having a first surface and a second surface, wherein the first surface comprises at least one convex-shaped portion and the second surface is substantially planar; at least one pair of first electrodes disposed on the first surface; and at least one second electrode disposed on the second surface; and a material disposed on the at least one second electrode, wherein the material is sensitive to the analyte; and measuring a change in resonating frequency of the convex crystal resonator.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through use of the accompanying drawings.

FIG. 1A schematic sectional view of an illustrative example of a convex crystal oscillator, arranged in accordance with at least some embodiments described herein.

FIG. 1B is a schematic top view of the illustrative example of the convex crystal oscillator shown in FIG. 1A.

FIG. 1C is a schematic bottom view of the illustrative example of the convex crystal oscillator shown in FIG. 1A.

FIG. 2A is a schematic sectional view of an illustrative example of a convex crystal oscillator, arranged in accordance with at least some embodiments described herein.

FIG. 2B is a schematic top view of the illustrative example of the convex crystal oscillator shown in FIG. 2A.

FIG. 2C is a schematic bottom view of the illustrative example of the convex crystal oscillator shown in FIG. 2A.

FIG. 2D depicts a cross-sectional view of an illustrative example of a convex crystal oscillator incorporated into a circuit.

FIG. 3 schematically shows an illustrative example of an oscillator circuit, arranged in accordance with at least some embodiments described herein.

FIG. 4 illustrates an example flow diagram of a process for fabricating a crystal oscillator, arranged in accordance with at least some embodiments described herein.

FIG. 5 depicts a resonance spectrum of a convex crystal oscillator.

FIG. 6 is an image of a non-limiting embodiment of wiring of a convex crystal oscillator.

FIG. 7A is a plot showing the change in oscillation frequency of a via-hole mounted crystal oscillator.

FIG. 7B is a plot showing the change in oscillation frequency of a conventional surface-mounted crystal oscillator.

FIG. 7C is a plot showing the change in oscillation frequency of a metal can type crystal oscillator.

FIG. 7D is a plot showing the change in oscillation frequency of a convex crystal oscillator.

FIG. 8 depicts an illustrative example of mounting where a convex crystal oscillator is used as an odor sensor.

FIG. 9 depicts an illustrative example of three crystal oscillators used for comparison with an embodiment of a convex crystal oscillator disclosed herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented here. It will be readily understood that the aspects of the present disclosure, as generally described herein, and illustrated in the Figures, can be arranged, substituted, combined, and designed in a wide variety of different configurations, all of which are explicitly contemplated and make part of this disclosure.

Disclosed in the present disclosure are crystal oscillators and methods for fabricating the crystal oscillators. Sensors comprising the crystal oscillators, and methods for using the sensors to detect one or more analytes are also disclosed herein.

### Crystal Oscillators

The present disclosure, in some embodiments, describes crystal oscillators. The crystal oscillators disclosed herein can, in some embodiments, avoid the need to hold the crystal element by its edges to suspend it in air. In some embodiments, this may be accomplished by using a convex-shaped crystal oscillator. In some embodiments, the electrode arrangement that causes the oscillation can effectively focus the oscillation energy in a convex part, such as in a convex shaped oscillator, by arranging them on one side of the crystal element. In some embodiments, the convex-shaped crystal oscillator can locally or partially amplify the oscillation energy.

In some embodiments, the crystal oscillator comprises a convex crystal resonator having a first surface and a second surface, wherein the first surface comprises at least one convex-shaped portion and the second surface is substantially planar; at least one pair of first electrodes disposed on the first surface; and at least one second electrode disposed on the second surface.

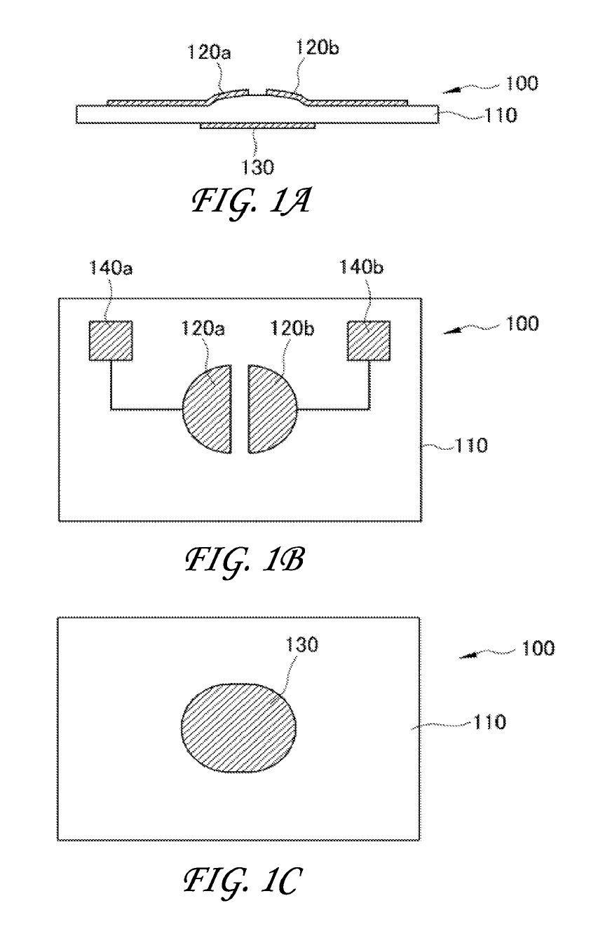

A non-limiting illustrative example of a crystal oscillator in accordance with the present disclosure is shown schematically in FIGS. 1A-C. FIGS. 1A-C are a schematic sectional view, a schematic top view and a schematic bottom view of the example crystal oscillator, respectively.

As illustrated in FIG. 1A, crystal oscillator 100 can include convex crystal resonator 110, a pair of first electrodes 120a and 120b, and a second electrode 130. As depicted in FIG. 1B, crystal oscillator 100 may include wiring pads 140a and 140b, for example on a first surface of convex crystal resonator 110, where the first surface has at least one convex-shaped portion. The pair of first electrodes 120a and 120b can be on the first surface of convex crystal resonator 110, where the first surface has at least one convex-shaped portion. In some embodiments, wiring pads 140a and 140b are connected to the pair of first electrodes 120a and 120b, for example by conducting wire. FIG. 1C shows that crystal oscillator 100 may include a second electrode 130 on a second surface of convex crystal resonator 110. In some embodiments, the second surface of convex crystal resonator 110 is substantially planar.

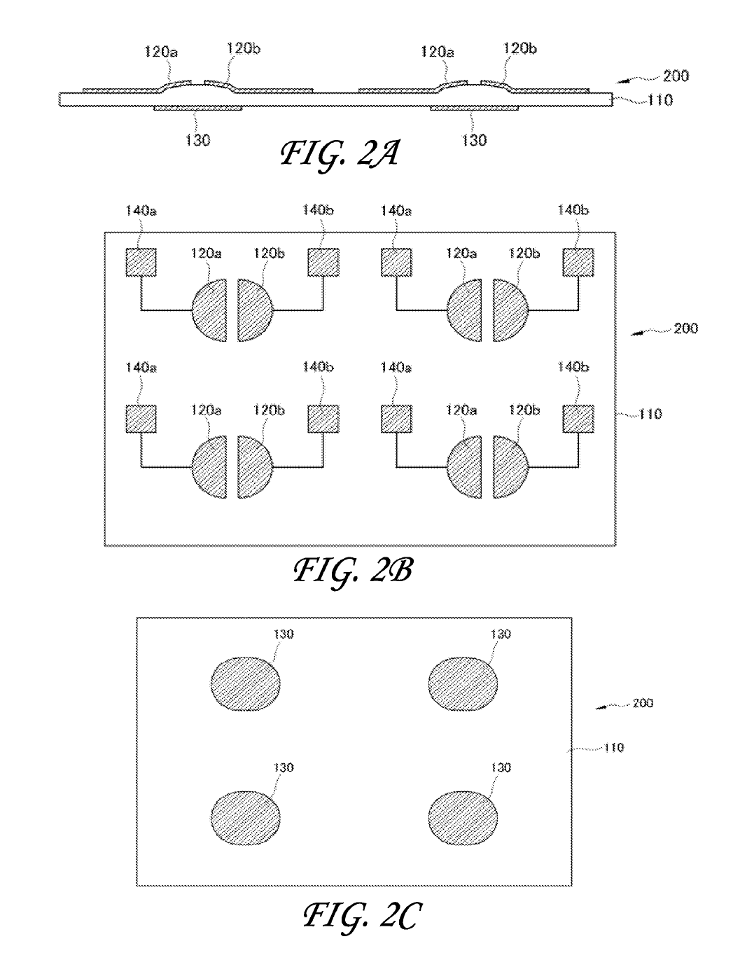

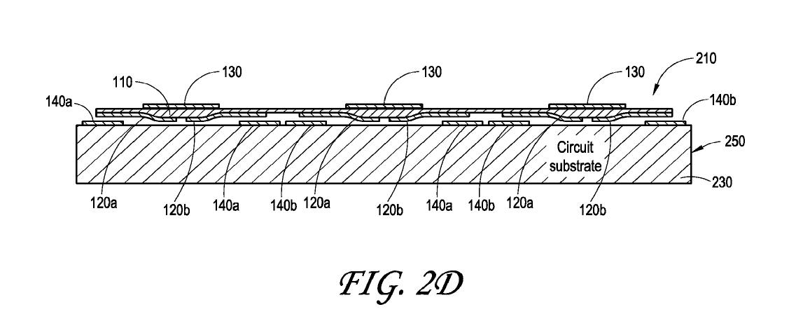

Another non-limiting illustrative example of a crystal oscillator is shown schematically in FIGS. 2A-C. FIGS. 2A-2C are a schematic sectional view, a schematic top view and a schematic bottom view of the example crystal oscillator, respectively.

As illustrated in FIG. 2A, crystal oscillator 200 may include convex crystal resonator 110, multiple pairs of first electrodes 120a and 120b, and a multiple second electrodes 130. As depicted in FIG. 2B, crystal oscillator 200 can include multiple (for example, two, three, four, five, or more) pairs of first electrodes 120a and 120b on a first surface of convex crystal resonator 110, where the first surface has at least one convex-shaped portion. Crystal oscillator 200 may also include multiple (for example, two, three, four, five, or more) wiring pads 140a and 140b. The wiring pads 140a and 140b can be on the first surface of convex crystal resonator 110. Wiring pads 140a and 140b can be connected to first electrodes 120a and 120b, for example by conducting wire. As depicted in FIG. 2C crystal oscillator 200 may include multiple (for example, two, three, four, five, or more) second electrodes 130 on a second surface of convex crystal resonator 110. In some embodiments, the second surface of convex crystal resonator 110 is substantially planar.

As disclosed herein, the first electrode and the second electrode can be, for example, independently an excitation electrode. The excitation electrode can, in some embodiments, be a suspected excitation electrode. The crystal oscillator can include one or more convex crystal resonators. For example, the crystal oscillator can include two, three, four, five, six, seven, eight, nine, ten, or more convex crystal resonators. The convex crystal resonator can include one or more pairs of first electrodes. For example, the convex crystal resonator can include two, three, four, five, six, seven, eight, nine, ten, or more pairs of first electrodes. The convex crystal resonator can include one or more second electrodes. For example, the convex crystal resonator can include two, three, four, five, six, seven, eight, nine, ten, or more second electrodes.

One or more of the crystal oscillators disclosed herein can be incorporated into a circuit. FIG. 2D illustrates a schematic sectional view of circuit 250 into which crystal oscillator 210 is incorporated. Crystal oscillator 210 can include convex crystal resonator 110 and multiple pairs of first electrodes 120a and 120b, and multiple second electrodes 130. Crystal oscillator 210 can include multiple (for example, two, three, four, five, or more) pairs of first electrodes 120a and 120b on a first surface of convex crystal resonator 110. Crystal oscillator 210 can also include multiple (for example, two, three, four, five, or more) wiring pads 140a and 140b. The wiring pads 140a and 140b can be on the first surface of convex crystal resonator 110. The wiring pads 140a and 140b can be connected to first electrodes 120a and 120b, for example, by conducting wire. The crystal oscillator 210 can be directly connected to the substrate 230 (or the wiring on the substrate). The number of crystal oscillator that can be incorporated into a circuit is not particularly limited. For example, the circuit can include one, two, three, four, five, six, seven, eight, nine, ten, or more crystal oscillators.

In some embodiments, the electrode wired to the crystal oscillator (for example crystal oscillator 200) to produce the crystal oscillation may be present on one or more surfaces of the crystal element. This may make it possible, in some embodiments, to place the one or more pairs of the first electrodes (for example the first electrodes 120a and 120b) of the convex crystal resonator (for example convex crystal resonator 110) and the second electrode 130 of the convex crystal resonator (for example convex crystal resonator 110) substantially opposite each other, allowing multiple oscillation points to be arranged on one or more crystal elements. This may make it possible to perform wiring operations for the electrode pad of the convex crystal resonator and the electrode pad of the crystal element substantially at once. Bonding may be carried out using, for example, a conductive adhesive.

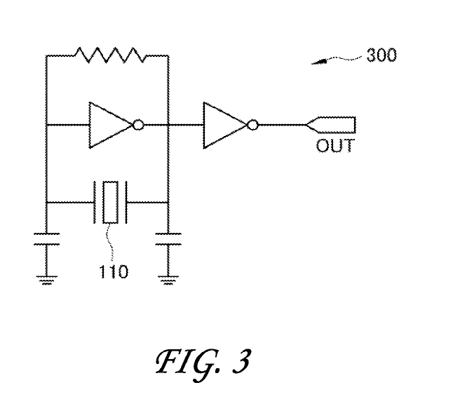

A non-limiting example of oscillator circuit in accordance with the present disclosure is illustrated in a diagram shown in FIG. 3. As depicted, oscillator circuit 300 can include convex crystal resonator 110. In some embodiments, convex crystal resonator 110 may be connected with other elements of oscillation circuit 300 via wiring pads (for example wiring pads 140a and 140b). An output terminal (OUT) of the oscillation circuit (for example, oscillation circuit 300) can be coupled with a frequency counter (not shown), so that the frequency counter may measure a resonating frequency of convex crystal resonator 110. A change in the resonating frequency may be used to detect an analyte associated with at least a material disposed on the convex crystal resonator and is sensitive to the analyte. In some embodiments, the circuit may oscillate a crystal oscillator at about the resonance frequency. In some embodiments, a Pierce BE oscillator circuit using a transistor may be used for the oscillator circuit 300. In other embodiments, a Pierce CB oscillator circuit may be used for the oscillator circuit 300. In some embodiments, an inverter IC may be used for the oscillator circuit 300.

In some embodiments, the first electrodes and/or the second electrodes may include a conductive material. Non-limiting examples of the conductive material may include gold, platinum, titanium, chromium, aluminum, nickel, silver, or a combination thereof. In some embodiments, the at least one pair of first electrodes include gold. In some embodiments, the second electrode includes gold.

The distance between the first electrodes is not particularly limited. By way of example, but not limitation, a distance between two first electrodes (for example, first electrode 120a and 120b) can be about 1 to 3 times of the length or width of the non-convex-shaped portion of convex crystal resonator. In some embodiments, the distance between two first electrodes can be about 0.1 μm to about 3000 μm. Specific examples of distance between two first electrodes include about 0.1 μm, about 1 μm, about 10 μm, about 100 μm, about 500 μm, about 1000 μm, about 2000 μm, about 3000 μm, and ranges between any two of these values (including endpoints). The thicknesses of the first electrode and second electrode are also not particularly limited. For example, the first electrode and/or the second electrode can have a thickness of about 0.001 μm to about 1 μm. Specific examples of thicknesses of the first electrode and/or the second electrode include about 0.001 μm, about 0.01 μm, about 0.1 μm, about 1 μm, and ranges between any two of these values (including endpoints).

In some embodiments, the convex crystal resonator may have one or more convex-shaped portions and one or more non-convex-shaped portions, so that the one or more convex-shaped portions may vibrate, while the one or more non-convex-shaped portions may not. In some embodiments, the convex crystal resonator may include AT-cut crystal. For example, in some embodiments, the AT-cut crystal may be quartz. In some embodiments, the convex crystal resonator may be a plano-convex quartz crystal resonator. In some embodiments, the first surface of the convex crystal resonator comprises one or more convex-shaped portions, and wherein the pair of first electrodes is aligned with at least one of the one or more convex-shaped portions. In some embodiments, the pair of first electrodes and the second electrode are aligned with at least one of the one or more convex-shaped portions of the convex quartz crystal resonator. In some embodiments, the convex crystal resonator is a plano-convex quartz crystal resonator having a first surface having a convex-shaped portion and a second surface that is substantially planar. In such cases, the first electrodes can be disposed on the first surface, while the second electrode can be disposed on the second surface.

In some embodiments, the first surface of the convex crystal resonator comprises two or more convex-shaped portions, and wherein each of the convex-shaped portions is aligned with each pair of first electrodes. In some embodiments, each pair of first electrodes and each second electrode are aligned with at least one convex-shaped portion of the convex quartz crystal resonator.

The shapes and sizes of the crystal oscillator and the convex crystal resonator are not particularly limited. The shapes and/or dimensions of the crystal oscillator and the convex crystal resonator may vary depending on the desired implementation. For example, the convex crystal resonator can have a square shape, a rectangular shape or a circular shape. In some embodiments, the convex crystal resonator has a square shape with a dimension of about 5 mm×5 mm.

The shapes and sizes of the one or more convex-shaped portions and the one or more non-convex-shaped portions of the convex crystal resonator are not particularly limited as well. The shapes and/or dimensions of the convex-shaped portions and the non-convex-shaped portions may vary depending on the desired implementation. In some embodiments, at least one of the one or more convex-shaped portions of the convex crystal resonator has a circular shape with a diameter of about 1 mm to about 2 mm. In some embodiments, at least one of the one or more non-convex-shaped portions of the convex crystal resonator has a circular shape with a diameter of about 1 mm to about 2 mm. By way of example, but not limitation, a thickness of the non-convex-shaped portion may be about 5 μm to about 2100 μm. Specific examples of thicknesses of the non-convex-shaped portion include about 5 μm, about 10 μm, about 50 μm, about 100 μm, about 500 μm, about 1000 μm, about 1500 μm, about 2000 μm, about 2100 μm, and ranges between any two of these values (including endpoints). The convex-shaped portion may be protruded from the surface of the non-convex shaped portion. The distance of this protrusion can be, for example, about 0.003 μm to about 30 μm, about 0.03 μm to about 30 μm, about 0.3 μm to about 30 μm, or about 3 μm to about 30 μm. Specific examples of the distance include about 0.003 μm, about 0.03 μm, about 0.3 μm, about 3 μm, about 10 μm, about 20 μm, about 30 μm, and ranges between any two of these values (including endpoints).

The thickness of the crystal oscillator is not particularly limited. For example, the crystal oscillator can have a thickness of less than about 1 mm, and in a further example, less than about 0.5 mm. In some embodiments, the crystal oscillator may have a thickness of about 0.1 mm, about 0.2 mm, about 0.3 mm, about 0.4 mm, about 0.5 mm, about 0.6 mm, about 0.7 mm, about 0.8 mm, about 0.9 mm, about 1 mm, or a range between any two of these values. In an embodiment, the crystal oscillator can have a thickness of about 0.1 mm.

In some embodiments, the crystal oscillator may have various fluctuations of oscillation frequency. For example, the crystal oscillator may have a fluctuation of oscillation frequency of less than about 0.1 ppm. In some embodiments, the crystal oscillator may have a fluctuation of oscillation frequency of less than about 0.01 ppm. In some embodiments, the crystal oscillator may have a fluctuation of oscillation frequency of about 0.001 ppm, about 0.002 ppm, about 0.003 ppm, about 0.004 ppm, about 0.005 ppm, about 0.006 ppm, about 0.007 ppm, about 0.008 ppm, about 0.009 ppm, about 0.01 ppm, about 0.02 ppm, about 0.03 ppm, about 0.04 ppm, about 0.05 ppm, about 0.06 ppm, about 0.07 ppm, about 0.08 ppm, about 0.09 ppm, about 0.1 ppm, or a range between any two of these values.

The length of the crystal oscillator is not particularly limited. In some embodiments, the crystal oscillator may have a length of less than about 5 mm. In some embodiments, the crystal oscillator can have a length of about 0.3 mm to about 5 mm. In some embodiments, the crystal oscillator may have a length of about 0.3 mm, about 0.4 mm, about 0.5 mm, about 0.6 mm, about 0.7 mm, about 0.8 mm, about 0.9 mm, about 1 mm, about 1.2 mm, about 1.4 mm, about 1.6 mm, about 1.8 mm, about 2.0 mm, about 2.2 mm, about 2.6 mm, about 2.8 mm, about 3.0 mm, about 3.2 mm, about 3.4 mm, about 3.6 mm, about 3.8 mm, about 4.0 mm, about 4.2 mm, about 4.4 mm, about 4.6 mm, about 4.8 mm, about 5.0 mm, or a range between any two of these values.

The width of the crystal oscillator is not particularly limited. In some embodiments the crystal oscillator may have a width of less than about 5 mm. In some embodiments, the crystal oscillator can have a width of about 0.3 mm to about 5 mm. In some embodiments, the crystal oscillator may have a width of about 0.3 mm, about 0.4 mm, about 0.5 mm, about 0.6 mm, about 0.7 mm, about 0.8 mm, about 0.9 mm, about 1 mm, about 1.2 mm, about 1.4 mm, about 1.6 mm, about 1.8 mm, about 2.0 mm, about 2.2 mm, about 2.6 mm, about 2.8 mm, about 3.0 mm, about 3.2 mm, about 3.4 mm, about 3.6 mm, about 3.8 mm, about 4.0 mm, about 4.2 mm, about 4.4 mm, about 4.6 mm, about 4.8 mm, about 5.0 mm, or a range between any two of these values.

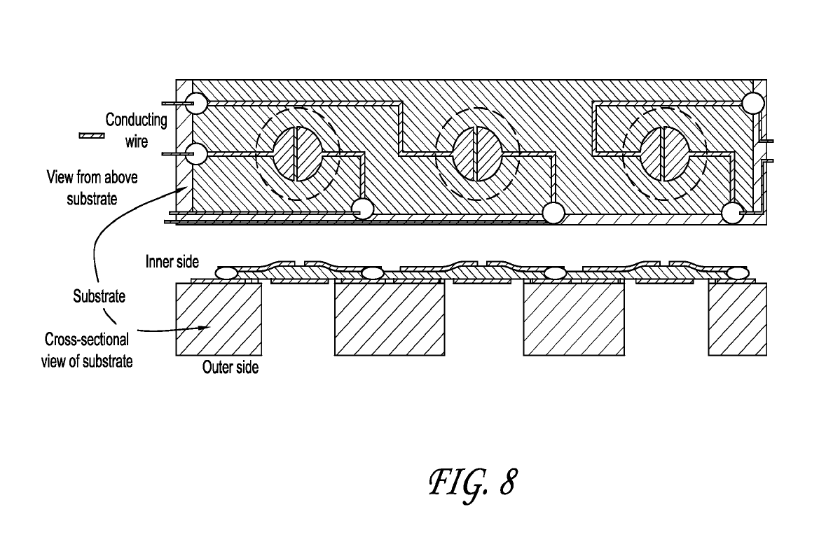

In some embodiments, the convex type crystal oscillator can oscillate when it is not substantially covered by a metal component, similar to the conventional surface-mounted type crystal oscillator. The convex crystal oscillator, in some embodiments, can be connected by directly bonding it to the wiring, and so its thickness can be made less than, for example, one tenth of the thickness of the conventional surface-mounted crystal oscillator. In some embodiments, the convex crystal oscillator of this invention can be directly connected to the substrate (or the wiring on the substrate). The convex crystal oscillator disclosed herein can be made thin. This may, in some embodiments, facilitate the incorporation of a crystal oscillator into a circuit. In addition, it is also possible for there to be a perforated section in the substrate and for one surface of the crystal oscillator to be exposed outside of the electronic circuit, making it suitable for cases where the crystal oscillator is used as an odor sensor. FIG. 8 shows an embodiment of mounting where a convex crystal oscillator is used as an odor sensor.

In some embodiments, the crystal oscillator further includes at least a pair of wiring pads (for example, wiring pads 140a and 140b) that is respectively connected to

each of the pair of first electrodes (for example, first electrodes 120a and 120b). The wiring pad can be disposed on a non-convex-shaped portion of convex crystal resonator. By way of example, but not limitation, the wiring pads can be made of the same conductive material as the first electrodes, such as, for example, gold, platinum, titanium, chromium, aluminum, nickel, silver, or any combination thereof.

The crystal oscillators disclosed herein may be applied to oscillation circuit elements for electronic circuit control in small mobile devices, such as a mobile telephones or smart phones, where the demands for circuit miniaturization, higher density, and weight reduction are increasing. The metal structure with a thickness of several millimeters in conventional devices becomes unnecessary, and in some embodiments, installation is possible in micrometer-order thickness, where the circuit wiring is added to the crystal oscillator thickness of around 100 μm.

In some embodiments, multiple oscillation points can be formed on a single element surface, making it possible to arrange multiple oscillation points on a single surface-mounted element. The crystal oscillators disclosed herein may also be applicable to sensor elements suitable for installation on small mobile devices, such as odor or gas sensors etc. that use multiple frequency oscillation points. In some embodiments, it is possible to support the detection of several varieties of odors with a single surface-mounted element where convex crystal oscillators are applied to odor sensors.

### Method for Fabricating a Crystal Oscillator

In some embodiments, a method for fabricating a crystal oscillator may include: providing a crystal substrate; forming at least one convex portion in the crystal substrate; forming at least one pair of first electrodes on a first surface of the at least one convex portion of the crystal substrate; and forming at least one second electrode on a second surface of the at least one convex portion of the crystal substrate. In some embodiments, the first surface of the convex portion may be a convex-shaped surface. In some embodiments, the second surface of convex portion may be substantially planar.

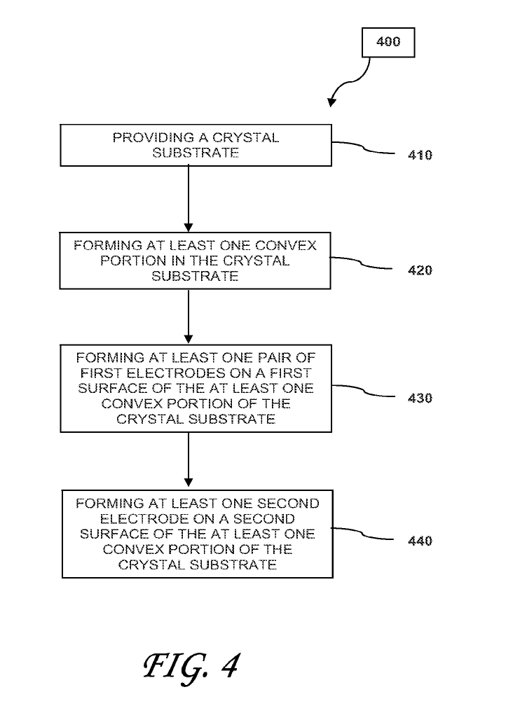

FIG. 4 illustrates a non-limiting example flow diagram of a method for fabricating a crystal oscillator, arranged in accordance with at least some embodiments described herein.

A non-limiting example process 400 may include one or more operations, actions, or functions as illustrated by one or more blocks 410, 420, 430, and/or 440. Although the blocks are illustrated as being performed sequentially, with block 410 first and block 440 last, various blocks may be divided into additional blocks, combined into fewer blocks, or eliminated, depending on the desired implementation. In some embodiments, one or more of the blocks can be performed at about the same time.

At block 410, a crystal substrate may be provided. By way of example, but not limitation, the crystal substrate may be an AT-cut crystal substrate. In some embodiments, the AT-cut crystal substrate can be quartz.

At block 420, at least one convex portion may be formed in the crystal substrate, and thus produce a convex crystal resonator (for example, convex crystal resonator 110 in FIGS. 1A-C and FIGS. 2A-D). In some embodiments, forming the at least one convex portion in the crystal substrate may include: applying a photoresist on a surface of the crystal substrate; patterning the photoresist on the surface of the crystal substrate; curing the patterned photoresist; and etching the crystal substrate and the patterned photoresist to form the convex portion. In some embodiments, forming the at least one convex portion may further include determining a sectional profile of the convex portion.

In some embodiments, the photoresist may be a positive photoresist. In other embodiments, the photoresist may include a diazonaphthoquinone (DNQ). In other embodiments, the photoresist may include an optionally substituted diazonaphthoquinone (DNQ), or a mixture of DNQ and a phenol formaldehyde resin. In some embodiments, patterning the photoresist may include patterning by exposure or heat. In some embodiments, patterning the photoresist may be performed based at least in part on the determined sectional profile of the convex portion. In some embodiments curing the patterned photoresist may include heating the patterned photoresist. In some embodiments, etching may be performed by reactive ion etching. In other embodiments, etching may include etching the crystal substrate and the patterned photoresist at different etching rates.

At block 430, at least one pair of the first electrodes (for example, first electrodes 120a and 120b in FIGS. 1A-C and FIGS. 2A-D) may be formed on a first surface of the at least one convex portion of the crystal substrate. In some embodiments, forming the at least one pair of first electrodes may include: depositing a conductive material on the first surface of the convex portion; and patterning the deposited conductive material to form the pair of first electrodes.

At block 440, at least one second electrode (for example, second electrode 130 in FIGS. 1A-C and FIGS. 2A-D) can be formed on a second surface of the at least one convex portion of the crystal substrate. In some embodiments, forming the at least one second electrode may include: depositing a conductive material on the second surface of the convex portion; and patterning the deposited conductive material to form the second electrode. In some embodiments, depositing the conductive material may include sputtering.

In some embodiments, forming the first electrodes and the second electrodes may include a conductive material. Non-limiting examples of the conductive material include gold, platinum, titanium, chromium, aluminum, nickel, silver, or a combination thereof. For example, in some embodiments, the conductive material is gold.

### Sensors

Also disclosed are sensors that incorporate the crystal oscillators disclosed herein. In some embodiments, the sensor can include a crystal oscillator, including a convex crystal resonator having a first surface and a second surface, wherein the first surface includes at least one convex-shaped portion and the second surface is substantially planar; at least one pair of first electrodes disposed on the first surface; and at least one second electrode disposed on the second surface; and a material disposed on the second electrode, wherein the material is sensitive to an analyte.

In some embodiments, the material that is sensitive to the analyte (for example, analyte-sensitive material) has a selective affinity for the analyte to be detected. The analyte can be a chemical. In some embodiments, the analyte is odor or gas. In some embodiments, the gas is a combustible gas, a flammable gas, a toxic gas, or a combination thereof. Non-limiting examples of the gas include CO, CO₂, CH₄, O₂, H₂, NH₃, C₂H₅OH, or a combination thereof.

The analyte-sensitive material can comprise, for example, a polycaprolactone, a polystyrene, a cycloolefin, an acrylic resin, or a combination thereof. For instance, polycaprolactone may detect phenylethyl alcohol (with a rose-like odor) but may not detect trichloroethylene, while polystyrene may detect both phenylethyl alcohol and trichloroethylene. The analyte-sensitive material may be coated on the second electrode (for example second electrode 130). In some embodiments, the analyte-sensitive material coats the entire surface of the second electrode. In some embodiments, the analyte-sensitive material coats a portion of the surface of the second electrode.

The sensor may include two or more crystal oscillators. In some embodiments, the sensor may detect multiple analytes simultaneously based on each resonant frequency change in each crystal oscillator. Those of ordinary skill in the art will recognize that the sensor may include any number and/or arrangement of crystal oscillators.

### Methods for Detecting Analytes

Methods for detecting an analyte are also disclosed herein. In some embodiments, the method can include: providing a sample suspected of containing an analyte; contacting a sensor with the sample, wherein the sensor comprises a crystal oscillator, comprising a convex crystal resonator having a first surface and a second surface, wherein the first surface comprises at least one convex-shaped portion and the second surface is substantially planar; at least one pair of first electrodes disposed on the first surface; and at least one second electrode disposed on the second surface; and a material disposed on the at least one second electrode, wherein the material is sensitive to the analyte; and measuring a change in resonating frequency of the convex crystal resonator. Any of the sensors disclosed in the present disclosure can be used in the method.

In some embodiments, the sample may be a gas sample. In some embodiments, the analyte may be odor or gas. In some embodiments, the gas sample may include a combustible gas, a flammable gas, a toxic gas, or a combination thereof.

### EXAMPLES

Additional embodiments are disclosed in further detail in the following examples, which are not in any way intended to limit the scope of the claims.

### Example 1

### Preparation of the Convex Crystal Oscillator Substrate

For the convex crystal oscillator, a prototype crystal substrate was manufactured by an etching process and gold deposition to produce a substrate with a resonant frequency of 17 MHz.

A positive photoresist was patterned on an AT-cut crystal substrate, exposing a surface of the crystal substrate. The exposed surface was circular in shape. The positive photoresist had a thickness of 100 μm and was heated to cure the resist pattern. After which, reactive ion etching was performed on the exposed surface to form a lens-shaped portion.

Gold was deposited on the lens-shaped portion of the crystal substrate by sputtering, and patterning was carried out by performing alignment and wet etching in order to form an excitation electrode on the center of the lens-shaped portion. Gold was also deposited by sputtering on the surface of the crystal substrate opposite to the excitation electrode on the reverse side of the crystal substrate to form a suspended electrode.

### Example 2

### Preparation of the Oscillator Circuit

A convex crystal oscillator substrate was prepared according to the procedure described in Example 1. A circuit was prototyped as an electronic circuit to oscillate the crystal oscillator at the resonance frequency. The circuit was made using a logic IC (inverter). TC74HCU04AP was used as a 5 V DC power supply, with a 1 MΩ resistor and a 10 pF capacitor.

### Example 3

### Oscillation Frequency Measurements

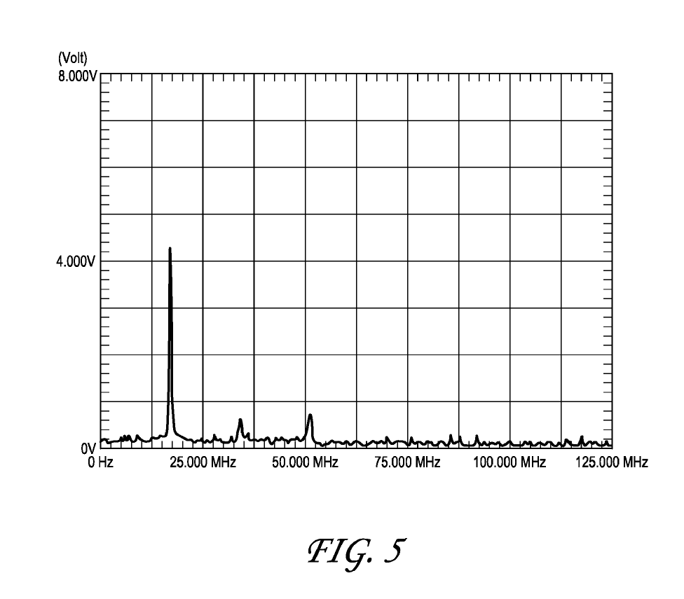

An oscillator circuit was prepared according to the procedure described in Example 2. A lead extending from the part of the oscillator circuit where the crystal oscillator was inserted was attached to the electrode pad section of the convex crystal oscillator, and oscillatory behavior was confirmed. The oscillation signal was detected by an oscilloscope, after which the signal was subjected to fast Fourier transform (FFT) analysis and was plotted as a resonance spectrum, from which the existence of resonant frequency peaks was confirmed. FIG. 5 shows a resonance spectrum of the convex crystal oscillator.

The example confirmed that the convex crystal oscillator prepared according to the present disclosure resonated at approximately 17 MHz. It was also confirmed that, although small, there were high-frequency peaks that were three-times higher than the 17 MHz basic frequency of the crystal oscillator.

### Example 4

### Frequency Measurements

An oscillator circuit was prepared according to the procedure described in Example 2. The frequency from the oscillation circuit was measured by a frequency counter (universal counter 53131A from Agilent (Santa Clara, Calif.)) via a coaxial cable, and the resulting oscillation frequency data was captured at 1-second intervals by a personal computer via a GP-IB communication card.

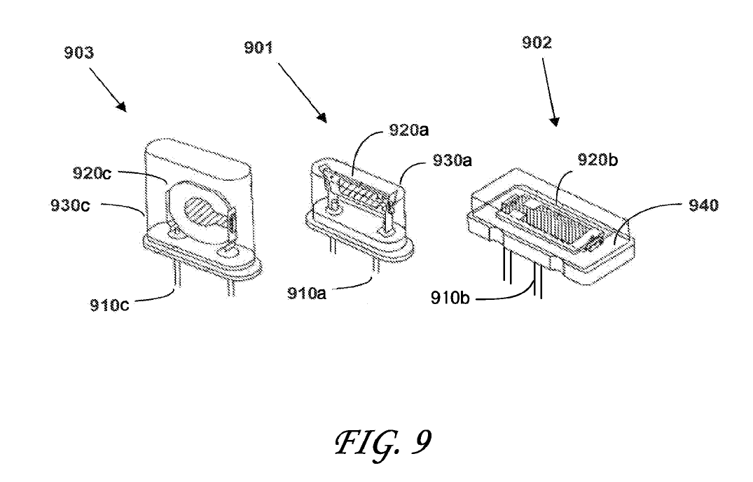

Additional crystal oscillators were used for comparison. A schematic illustration of the three crystal oscillators used is depicted in FIG. 9. The crystal oscillators used for comparison were: a via-hole mounted crystal oscillator electronic component (20 MHz) 901, the leads of which were fixed in the holes of a printed circuit board; a 17 MHz surface-mounted crystal oscillator (length: 8 mm, width: 4.5 mm, height: 1.8 mm) 902; and a crystal oscillator used in a crystal oscillator sensor (30 MHz: a metal can type crystal oscillator with the cylindrical package part removed) 903.

As existing crystal of a crystal oscillator used in an electronic component oscillates at high frequency, it is usually sealed in a metal or resin to become stable. In all crystal oscillators 901, 902, and 903, the crystals 920a, 920b, and 920c are suspended. In the via-hole mounted crystal oscillator electronic component (20 MHz) 901, one end of the crystal oscillator plate 920a was connected to lead wires 910a so as to suspend the crystal 920a in a metal can 930a. The metal can 930a was sealed. In the 17 MHz surface-mounted crystal oscillator 902, a crystal plate 920b was suspended in a resin can 940 and connected to wires 910b. The resin can 940 was sealed. In the crystal oscillator used in a crystal oscillator sensor 903, a metal can 930c was removed so that the crystal 920c was not sealed in the metal can 930c.

For crystal oscillator 903 in which the exterior metal can 930c was removed from the electronic component, the signal variation ΔF was unstable, as compared to the signal variation ΔF of crystal oscillators 901 and 902. Therefore, from observing the signal variations in crystal oscillators 901 to 903, one may consider suspending the crystal in a metal can to achieve stable signals. However, one of ordinary skill in the art would appreciate that it would be difficult to make the oscillator compact and thin in the presence of a metal can. In contrast, a convex-type crystal oscillator disclosed herein has no exterior metal can and the crystal oscillator is directly connected to wires. As shown herein, compared to the existing oscillators used in electronic components (for example, the crystal oscillators 901 and 902 described in this Example), signal variation ΔF of the convex-type crystal oscillator disclosed herein is smaller, in some instances approximately one-tenth the value of that of the conventional oscillators. Accordingly, convex-type crystal oscillators disclosed herein are capable of generating stable oscillating signals.

### Example 5

### Wiring

The oscillation stability of the crystal oscillators from Example 4 was evaluated. The crystal oscillator (3) and the convex crystal oscillator were each fixed to a glass block surface. For oscillator (1) or the via-hole mounted crystal oscillator, the lead wires of the via-hole mounted crystal oscillator (20 MHz) were inserted into holes in an oscillation circuit board. Wiring for oscillator (2) or the 17 MHz surface-mounted crystal oscillator, was carried out by directly bonding it with conductive adhesive to copper foil lines formed on the glass block and connecting the copper foil lines and the oscillation circuit with lead wires.

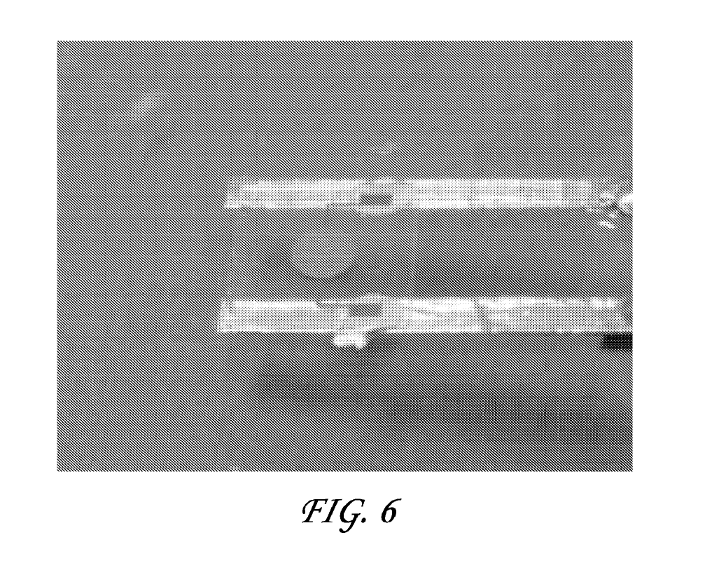

Wiring for oscillator (3) or the crystal oscillator used in the crystal oscillator sensor, was carried out by bonding an acrylic piece that secures the metal can holder to the glass block surface, fixing the lead wires of the crystal oscillator, and then bonding the lead wires and the copper foil lines formed on the glass block with conductive adhesive. The copper foil lines and the oscillation circuit were then connected by lead wires to simulate a surface-mounted condition. Wiring for the convex crystal oscillator was carried out by directly bonding it with conductive adhesive to copper foil lines formed on a glass block and connecting the copper foil lines and the oscillation circuit with lead wires to simulate a surface-mounted condition. FIG. 6 shows an image of a non-limiting embodiment of wiring for the convex crystal oscillator as disclosed in the present disclosure.

### Example 6

### Frequency Stability

As detailed above, a surface-mounted condition was simulated by directly connecting the convex crystal oscillator and the conventional surface mounted crystal oscillator onto copper foil lines formed on glass blocks. In addition, the metal can type crystal oscillator was also installed on a glass block surface by creating an acrylic underlay. A comparison of the oscillation conditions was made by independently connecting each crystal oscillator to the same oscillation circuit, oscillating them, and measuring the oscillation frequencies.

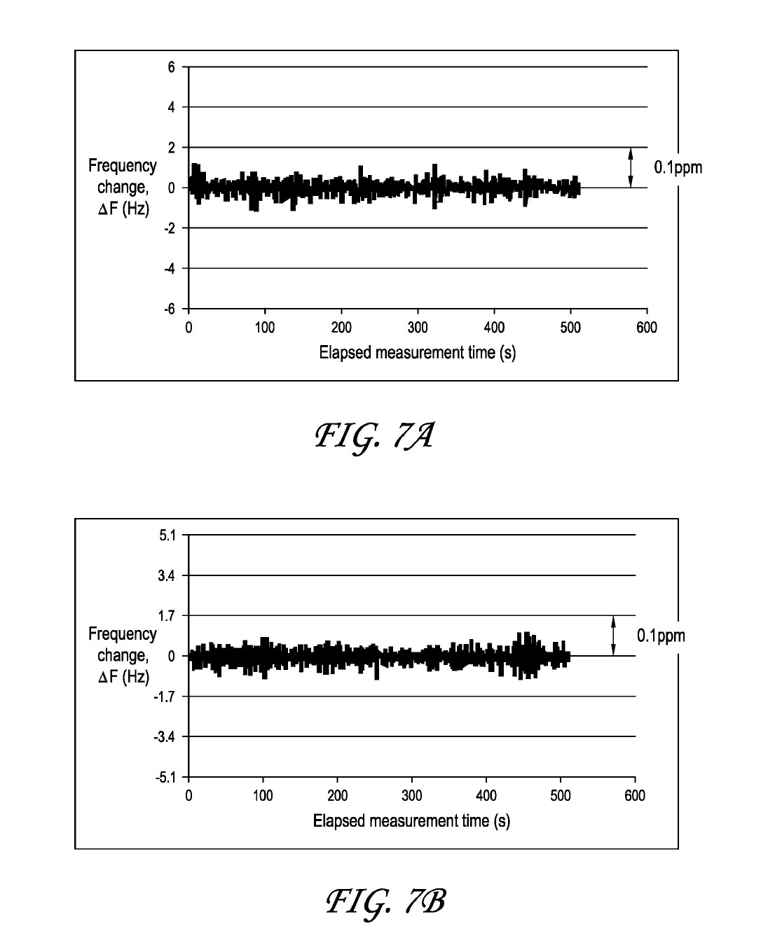

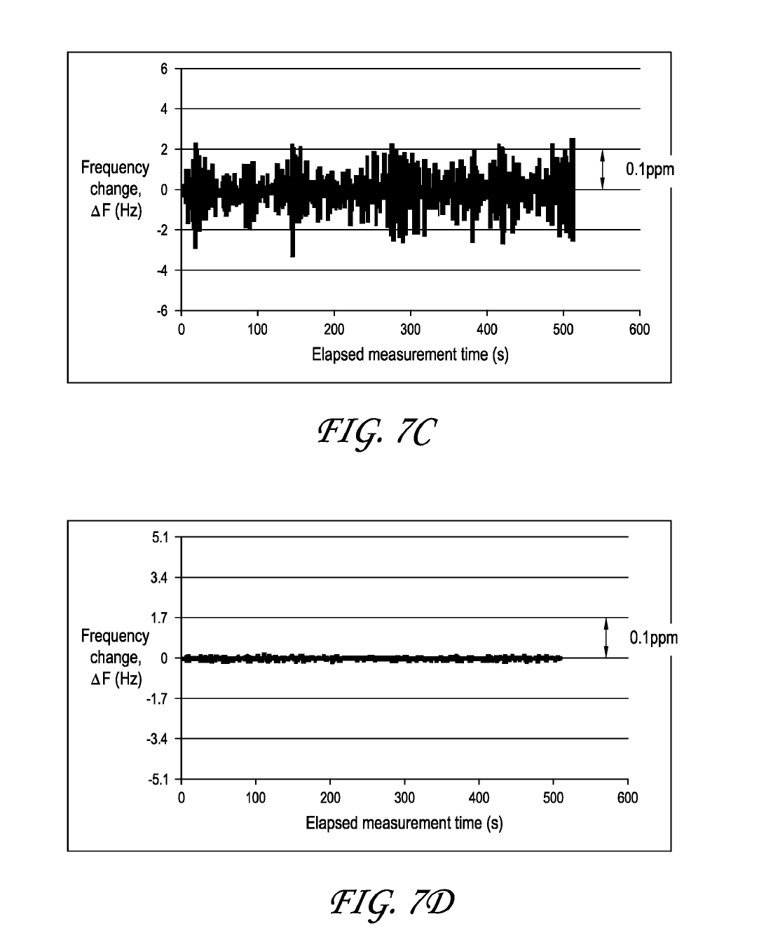

The oscillation frequency was measured at one-second intervals and data (500 seconds) for the change in oscillation frequency (ΔF) for each second was acquired. The via-hole mounted crystal oscillator (20 MHz) is a standard model used as a crystal oscillator device and can be considered to simulate the standard oscillation conditions of an electronic circuit. FIG. 7A shows a plot of the change in oscillation frequency of the via-hole mounted crystal oscillator.

FIG. 7B shows a plot of the results of the change in oscillation frequency of the conventional surface-mounted crystal oscillator. The range of fluctuation of the oscillation frequency for both the via-hole mounted crystal oscillator and the conventional surface-mounted crystal oscillator was less than 0.1 ppm, and no significant difference was observed.

FIG. 7C shows a plot of the change in oscillation frequency of the metal can type crystal oscillator. The metal can type crystal oscillator did not have a metal cover and the change in oscillation frequency sometimes exceeded 0.1 ppm. Large fluctuations were observed in comparison with the via-hole mounted crystal oscillator and the conventional surface-mounted crystal oscillator.

FIG. 7D shows a plot of the change in oscillation frequency of the convex crystal oscillator. The frequency change of the convex crystal oscillator was small, and it was stable in comparison with the other crystal oscillators.

In a comparison of the changes in oscillation frequency ΔF/F, the via-hole mounted (oscillator (1)) and the conventional surface-mounted crystal oscillator electronic components (oscillator (2)) have similar values, whereas the metal can type with the cover removed (oscillator (3)) has a value 3 to 4 times larger but had low stability. TABLE 1 shows a comparison of frequency change characteristics, including the average value of oscillation frequency F(l), the average value of the change in oscillation frequency ΔF (2), and ΔF/F (2/1 ppm).

TABLE 1
Comparison of frequency change characteristics

| | Via-hole | | Metal Can | |
|---|---|---|---|---|
| | Type | Conventional Surface- | Type | |
| | (Oscillator | Mounted Type | (Oscillator | Convex |
| | (1)) | (Oscillator (2)) | (3)) | Type |
| Average Oscillation | 20,002,957 | 16,934,112 | 30,032,265 | 17,110,690 |
| Frequency, F | | | | |
| Average Change in | 0.246 | 0.260 | 1.267 | 0.040 |
| Oscillation | | | | |
| Frequency ΔF | | | | |
| ΔF/F (ppm) | 0.012 | 0.015 | 0.042 | 0.002 |

As shown in this example, although the convex type crystal oscillator disclosed herein has no cover and is directly attached to the wiring of the substrate, it exhibited good stability.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

One skilled in the art will appreciate that, for this and other processes and methods disclosed herein, the functions performed in the processes and methods can be implemented in differing order. Furthermore, the outlined steps and operations are only provided as examples, and some of the steps and operations can be optional, combined into fewer steps and operations, or expanded into additional steps and operations without detracting from the essence of the disclosed embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A crystal oscillator, comprising
a convex crystal resonator having a first surface and a second surface, wherein the first surface comprises at least one convex-shaped portion and the second surface is substantially planar;
at least one pair of first electrodes disposed on the first surface; and
at least one second electrode disposed on the second surface.

2. The crystal oscillator of claim 1, wherein the at least one pair of first electrodes and the at least one second electrode comprise a conductive material.

3. The crystal oscillator of claim 2, wherein the conductive material comprises gold, platinum, titanium, chromium, aluminum, nickel, silver, or a combination thereof.

4. The crystal oscillator of claim 1, wherein the at least one pair of first electrodes and the at least one second electrode comprise gold.

5. The crystal oscillator of claim 1, wherein the convex crystal resonator comprises AT-cut crystal.

6. (canceled)

7. (canceled)

8. The crystal oscillator of claim 1,
wherein the first surface of the convex crystal resonator comprises one convex-shaped portion, and wherein the at least one pair of first electrodes is aligned with the one convex-shaped portion.

9. The crystal oscillator of claim 8, wherein at least one second electrode is aligned with the one convex-shaped portion.

10. The crystal oscillator of claim 1, wherein the first surface of the convex crystal resonator comprises two or more convex-shaped portions, wherein the at least one pair of first electrodes includes a plurality of pairs of first electrodes, and wherein each of the two or more convex-shaped portions is aligned with a respective pair of first electrodes of plurality of pairs of first electrodes.

11. The crystal oscillator of claim 10, wherein the at least one second electrode includes a plurality of second electrodes wherein each of the two or more convex-shaped portions is aligned with a respective second electrode of the plurality of second electrodes.

12. The crystal oscillator of claim 1, wherein the crystal oscillator has a thickness of less than about 1 mm.

13. The crystal oscillator of claim 1, wherein the crystal oscillator has a thickness of less than about 0.5 mm.

14. The crystal oscillator of claim 1, wherein the crystal oscillator has a thickness of about 0.1 mm.

15. The crystal oscillator of claim 1, wherein the crystal oscillator has a fluctuation of oscillation frequency of less than about 0.1 ppm.

16. The crystal oscillator of claim 1, wherein the crystal oscillator has a fluctuation of oscillation frequency of less than about 0.01 ppm.

17. The crystal oscillator of claim 1, wherein the crystal oscillator has a length of less than about 5 mm.

18. The crystal oscillator of claim 17, wherein the crystal oscillator has a width of less than about 5 mm.

19. (canceled)

20. A method to fabricate a crystal oscillator, the method comprising:
providing a crystal substrate;
forming at least one convex portion in the crystal substrate;
forming at least one pair of first electrodes on a first surface of the at least one convex portion of the crystal substrate; and
forming at least one second electrode on a second surface of the at least one convex portion of the crystal substrate.

21. The method of claim 20, wherein the first surface of the at least one convex portion includes a convex-shaped surface.

22. The method of claim 21, wherein the second surface of the at least one convex portion is substantially planar.

23. The method of claim 20, wherein forming the at least one convex portion in the crystal substrate comprises:
applying a photoresist on a surface of the crystal substrate;
patterning the photoresist on the surface of the crystal substrate to form a patterned photoresist;
curing the patterned photoresist; and
etching the crystal substrate and the patterned photoresist to form the at least one convex portion.

24. The method of claim 23, wherein forming the at least one convex portion further comprises determining a sectional profile of the at least one convex portion.

25. The method of claim 23, wherein applying the photoresist comprises applying a diazonaphthoquinone (DNQ).

26. The method of claim 23, wherein patterning the photoresist comprises patterning by exposure or heat.

27. The method of claim 23, wherein patterning the photoresist is based, at least in part, on sectional profile of the at least one convex portion.

28. (canceled)

29. The method of claim 23, wherein applying the photoresist includes applying a positive photoresist.

30. The method of claim 29, wherein applying the photoresist includes applying a photoresist that comprises an optionally substituted diazonaphthoquinone (DNQ), or a mixture of DNQ and a phenol formaldehyde resin.

31. The method of claim 23, wherein etching includes etching the crystal substrate and the patterned photoresist via reactive ion etching.

32. The method of claim 23, wherein etching comprises etching the crystal substrate and the patterned photoresist at different etching rates.

33. The method of claim 20, wherein forming the at least one pair of first electrodes comprises:
depositing a conductive material on the first surface of the at least one convex portion; and
patterning the conductive material deposited on the first surface to form the at least one pair of first electrodes.

34. The method of claim 20, wherein forming the at least one second electrode comprises:
depositing a conductive material on the second surface of the at least one convex portion; and
patterning the conductive material deposited on the second surface to form the at least one second electrode.

35. (canceled)

36. The method of claim 33, wherein depositing the conductive material comprises depositing gold, platinum, titanium, chromium, aluminum, nickel, silver, or a combination thereof.

37. (canceled)

38. (canceled)

39. A sensor, comprising;
a crystal oscillator, comprising;
a convex crystal resonator having a first surface and a second surface, wherein the first surface comprises at least one convex-shaped portion and the second surface is substantially planar;
at least one pair of first electrodes disposed on the first surface;
at least one second electrode disposed on the second surface; and
a material disposed on the at least one second electrode, wherein the material is sensitive to an analyte.

40. The sensor of claim 39, wherein the material that is sensitive to the analyte has a selective affinity for the analyte.

41. The sensor of claim 39, wherein the analyte includes an odor or gas.

42. The sensor of claim 41, wherein the gas includes a combustible gas, a flammable gas, a toxic gas, or a combination thereof.

43. The sensor of claim 41, wherein the gas includes CO, CO₂, CH₄, O₂, H₂, NH₃, C₂H₅OH, or a combination thereof.

44. A method to detect an analyte, the method comprising:
providing a sample suspected to contain an analyte;
contacting a sensor with the sample, wherein the sensor comprises,
a crystal oscillator, comprising
a convex crystal resonator having a first surface and a second surface, wherein the first surface comprises at least one convex-shaped portion and the second surface is substantially planar;
at least one pair of first electrodes disposed on the first surface; and
at least one second electrode disposed on the second surface; and
a material disposed on the at least one second electrode, wherein the material is sensitive to the analyte; and
determining a change in resonance frequency of the convex crystal resonator.

45. The method of claim 44, wherein the sample includes a gas sample.

46. The method of claim 44, wherein the analyte includes an odor or gas.

47. The method of claim 45, wherein the gas sample comprises a combustible gas, a flammable gas, a toxic gas, or a combination thereof.
